(19) United States
(12) Patent Application Publication
(10) Pub. No.: US 2020/0259034 A1
(43) Pub. Date: Aug. 13, 2020

(54) A DETECTING SUBSTRATE, A MANUFACTURING METHOD THEREOF AND A PHOTOELECTRIC DETECTION DEVICE

(71) Applicant: BOE TECHNOLOGY GROUP CO., LTD., Beijing (CN)

(72) Inventors: Rui Huang, Beijing (CN); Huili WU, Beijing (CN)

(73) Assignee: BOE TECHNOLOGY GROUP CO., LTD., Beijing (CN)

(21) Appl. No.: 16/611,377

(22) PCT Filed: Mar. 22, 2019
(86) PCT No.: PCT/CN2019/079168

§ 371 Date: Nov. 6, 2019

(30) Foreign Application Priority Data
Mar. 22, 2018 (CN) 201810241361.3

(51) Int. Cl. H01L 31/105; H01L 31/18

(52) U.S. Cl. CPC H01L 31/105; H01L 31/1804

(57) ABSTRACT

The present disclosure provides a detecting substrate, a manufacturing method thereof and a photoelectric detection device including the detecting substrate. The detecting substrate including: a substrate; and a photoelectric conversion element formed on the substrate, wherein the photoelectric conversion element is a PIN device comprising a first doped semiconductor layer, an intrinsic semiconductor layer and a second doped semiconductor layer, wherein a side wall of the intrinsic semiconductor layer is covered by an etching protective layer.

### CROSS-REFERENCE TO RELATED APPLICATION

This application claims a priority to Chinese Patent Application No. 201810241361.3 filed in China on Mar. 22, 2018, the disclosure of which is incorporated herein in its entirety by reference.

### TECHNICAL FIELD

The present disclosure relates to a field of a photoelectric technology, and in particular to a detecting substrate, a manufacturing method thereof and a photoelectric detection device including the detecting substrate.

### BACKGROUND

At present, X-ray detection is widely used in medical, safety, non-destructive testing and other fields, and plays an increasingly important role. X-ray digital radiography (DR) is widely used, which can be divided into two types: direct DR and indirect DR. An indirect X-ray detector has been widely developed and used due to mature development, relatively low cost and good device stability.

An X-ray detector includes an array substrate including a Thin Film Transistor (TFT) and a photodiode. Under an irradiation of X-ray, a scintillator layer and a fluorescent layer of the X-ray detector convert X-ray photons into visible light, and then convert the visible light into an electrical signal under an action of the photodiode. The electrical signal is read and output by the thin film transistor, then a display image is obtained. The photodiode is a key component of the indirect X-ray detector array substrate. A conversion efficiency has significant impact on X-ray dose, resolution of X-ray imaging, image response speed and other key indicators.

### SUMMARY

Embodiments of the present disclosure provide a detecting substrate, a manufacturing method thereof and a photoelectric detection device including the detecting substrate.

Embodiments of the present disclosure provide a detecting substrate, including: a substrate; and a photoelectric conversion element, formed on the substrate, the photoelectric conversion element is a PIN device comprising a first doped semiconductor layer, an intrinsic semiconductor layer and a second doped semiconductor layer, wherein a side wall of the intrinsic semiconductor layer is covered by an etching protective layer.

Optionally, the etching protective layer is made of transparent insulating material.

Optionally, the detecting substrate further including: an etching repair layer, formed between the intrinsic semiconductor layer and the etching protective layer.

Optionally, the etching repair layer is also formed between the intrinsic semiconductor layer and the first doped semiconductor layer.

Optionally, the etching repair layer is made of transparent insulating material.

Optionally, a refractive index of the intrinsic semiconductor layer is larger than that of the etching protective layer.

Optionally, the photoelectric conversion element further includes: a packaging layer covering the etching protective layer, a refractive index of the etching protective layer being larger than that of the packaging layer.

Optionally, the first doped semiconductor layer is made of transparent material.

Optionally, the first doped semiconductor layer is a P-type semiconductor layer and the second doped semiconductor layer is an N-type semiconductor layer, or, the first doped semiconductor layer is an N-type semiconductor layer and the second doped semiconductor layer is a P-type semiconductor layer.

Embodiments of the present disclosure also provide a photoelectric detection device including the detecting substrate described above.

Embodiments of the present disclosure also provide a method for manufacturing a detecting substrate, including: forming a first doped semiconductor thin film on a substrate; forming an etching protective thin film on the substrate, etching and removing a part of the etching protective thin film at a region where a PIN device is to be formed with an intrinsic semiconductor layer; forming an intrinsic semiconductor thin film on the etching protective thin film after etching at the region where a PIN device is to be formed; forming a second doped semiconductor thin film on the intrinsic semiconductor thin film, wherein one of the first doped semiconductor thin film and the second doped semiconductor thin film is a P-type semiconductor thin film and the other is an N-type semiconductor thin film; etching the etching protective thin film, the intrinsic semiconductor thin film and the second doped semiconductor thin film, and forming a PIN device comprising a first doped semiconductor layer, the intrinsic semiconductor layer and a second doped semiconductor layer, wherein an etching protective layer is formed by the remaining etching protective thin film covering a side wall of the intrinsic semiconductor layer.

Optionally, subsequent to etching and removing the part of the etching protective thin film at a region where a PIN device is to be formed, the method further includes:

forming an etching repair layer on an etched surface of the etching protective thin film.

Optionally, when etching and removing the part of the etching protective thin film at the region where a PIN device is to be formed, an inclination angle of an etching surface of the etching protective thin film at the region where a PIN device is to be formed is determined based on a refractive index of the intrinsic semiconductor layer and a refractive index of the etching protective thin film.

Optionally, when the PIN device is formed by etching, an inclination angle of an external sidewall of the etching protective layer is determined based on a refractive index of an encapsulation layer to be formed on the PIN device and a refractive index of the etching protective thin film.

Optionally, the etching protective thin film is made of transparent insulating material.

Optionally, the etching repair layer is made of transparent insulating material.

### BRIEF DESCRIPTION OF THE DRAWINGS

FIG. 1 is a schematic diagram illustrating a detecting substrate of one embodiment of the present disclosure;

FIG. 2 is a schematic diagram illustrating a detecting substrate of another embodiment of the present disclosure;

FIG. 3 is a schematic diagram illustrating a detecting substrate of another embodiment of the present disclosure;

FIG. 4 is a flowchart illustrating a method for manufacturing a detecting substrate of one embodiment of the present disclosure;

FIG. 5-FIG. 10 are schematic diagrams illustrating processes of a method for manufacturing a detecting substrate of another embodiment of the present disclosure.

### DETAILED DESCRIPTION

Embodiments of the present disclosure will be illustrated in detail hereinafter with reference to the accompanying drawings. The embodiments of the present disclosure are given in an exemplary manner and are not limited to the present disclosure.

The embodiments of the present disclosure provide a detecting substrate, a manufacturing method thereof and a photoelectric detection device including the detecting substrate, which may improve effectively a performance of an X-ray detector. A PIN device is used as a photoelectric conversion element in the detecting substrate. By providing a side wall etching protective layer to an intrinsic semiconductor layer of the PIN device, a side wall etching area of the intrinsic semiconductor layer is reduced, a side wall leakage current is reduced, and a signal-to-noise ratio of the detecting substrate is improved.

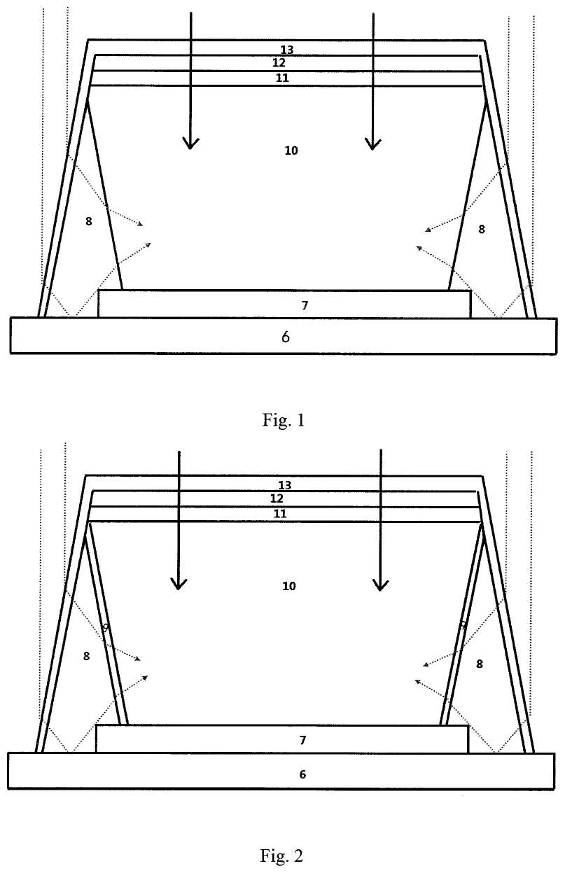

FIG. 1 is a schematic diagram illustrating a detecting substrate of one embodiment of the present disclosure. The detecting substrate of the embodiment of the present disclosure is an array substrate including a Thin Film Transistor (TFT) and a PIN device. Since improvements made by the embodiments of the present disclosure mainly lie in a structure of the PIN device, in order to clearly describe an inventive concept of the present disclosure, the PIN device part is mainly shown in FIG. 1, and the thin film transistor part may be referred to FIG. 8.

The detecting substrate of the embodiment of the present disclosure includes a substrate 1 (referring to FIG. 8), a photoelectric conversion element formed on the substrate and an etching protective layer 8, a passivation layer 13 is formed on an external sidewall of the photoelectric conversion element and the etching protective layer.

The photoelectric conversion element is composed of a PIN device, for example, a PIN photodiode. In an example shown in FIG. 1, the PIN photodiode includes a lower electrode 6, a first doped semiconductor layer 7, an intrinsic semiconductor layer 10, a second doped semiconductor layer 11 and an upper electrode 12 formed by successive stacking from the substrate side. The second doped semiconductor layer 11 is a P-type when the first doped semiconductor layer 7 is an N-type semiconductor layer. The second doped semiconductor layer 11 is an N-type semiconductor layer when the first doped semiconductor layer 7 is a P-type semiconductor layer. The intrinsic semiconductor layer 10 is to generate a large amount of electron-hole pairs after absorbing incident light, so that the PIN device may convert an optical signal into an electrical signal. The intrinsic semiconductor layer 10 may be an intrinsic amorphous silicon layer or an intrinsic germanium layer, etc.

The etching protective layer 8 is formed on a side wall of the PIN device and covers a side wall of the intrinsic semiconductor layer 10. The etching protective layer 8 is to protect the side wall of the intrinsic semiconductor layer 10 when etching and forming a single PIN device, so that the side wall of the intrinsic semiconductor layer 10 may be avoided as much as possible from an influence of an etching process in a manufacturing process. Thus forming material surface defects may be avoided, a smoothness of the side wall surface of the intrinsic semiconductor layer 10 may be improved, and a leakage current at the side wall of the intrinsic semiconductor layer 10 may be reduced effectively.

On the other hand, as shown in FIG. 1, in the PIN device of the detecting substrate according to the embodiment of the present disclosure, in addition to absorbing incident light represented by solid lines, incident light as shown by dotted lines may irradiate into the intrinsic semiconductor layer 10 after passing through the etching protective layer 8. Therefore, compared with a PIN device of a detecting substrate in the related art which usually absorbs incident light represented by solid lines in FIG. 1, the PIN device of the detecting substrate in the embodiment of the present disclosure may absorb more incident light.

According to some embodiments of the present disclosure, the etching protective layer 8 is made of transparent insulating material, such as silicon oxide, silicon nitride etc., to increase an incident efficiency and avoid affecting photoelectric conversion. According to some embodiments of the present disclosure, the etching protective layer 8 covering the side wall of the intrinsic semiconductor layer 10 has a pyramid cross section, as shown in FIG. 1. When the incident light is perpendicular to the substrate, the light incident irradiating into a side of the etching protective layer 8 far from the intrinsic semiconductor layer 10 will be deflected and directed into the intrinsic semiconductor layer 10, so that more incident light may be absorbed by the intrinsic semiconductor layer 10.

According to some embodiments of the present disclosure, a refractive index of the intrinsic semiconductor layer 10 is larger than that of the etching protective layer 8, so that the incident light entering the intrinsic semiconductor layer 10 from the etching protective layer 8 may be refracted at a required angle and absorbed as much as possible by the intrinsic semiconductor layer 10. However, the technical scheme of the present disclosure is not limited to this. According to specific application occasions and requirements, the cross-section shape and/or the refractive index of the etching protective layer 8 may be set differently as long as the etching protective layer 8 is suitable for directing more light into a part of the intrinsic semiconductor layer 10.

According to some embodiments of the present disclosure, by arranging the etching protective layer 8 on the side wall of the intrinsic semiconductor layer 10 of the PIN device in the detecting substrate, etching the side wall of the intrinsic semiconductor layer 10 is avoided, or an etching area of the side wall of the intrinsic semiconductor layer 10 is reduced, a leakage current caused by the surface defects of crystal materials due to etching at the side wall of intrinsic semiconductor layer 10 is reduced, a light guide structure of the etching protective layer 8 may increase the incident light absorbed by the intrinsic semiconductor layer 10, and a signal-to-noise ratio of the detecting substrate is improved.

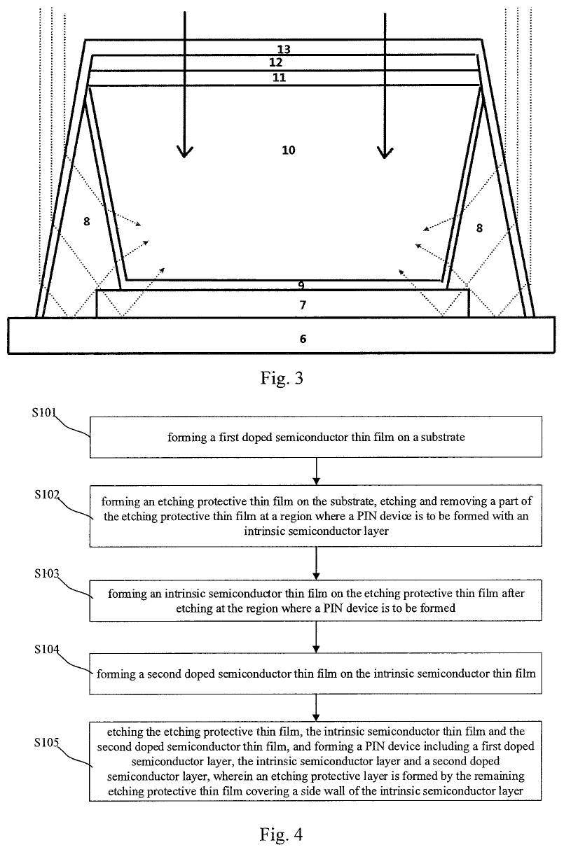

FIG. 2 is a schematic diagram illustrating a detecting substrate of another embodiment of the present disclosure.

As shown in FIG. 2, the detecting substrate according to the embodiment of the present disclosure shown in FIG. 1 further including an etching repair layer 9 formed between the intrinsic semiconductor layer 10 and the etching protective layer 8. The etching repair layer 9 is to repair an etched surface of an inner wall of the etching protective layer 8. The etching repair layer 9 may also made of a transparent insulating material, such as silicon oxide, silicon nitride etc. The etching repair layer 9 and the etching protective layer 8 may be made of the same material or different materials.

In the embodiment of the present disclosure, the etching protective layer 8 is arranged at the side wall of the intrinsic semiconductor layer 10 of the PIN device in the detecting substrate and the etching repair layer 9 is arranged between the etching protective layer 8 and the side wall of the intrinsic semiconductor layer 10, so that a smoothness of the side wall surface of the intrinsic semiconductor layer 10 may be improved, and a leakage current at the side wall of the intrinsic semiconductor layer 10 may be reduced effectively. Through the detecting substrate according to the embodiment of the present disclosure, a dark current (including a surface leakage current and an intrinsic dark current) in the PIN device may be reduced by two orders of magnitude and a signal-to-noise ratio of the detecting substrate may be improved effectively.

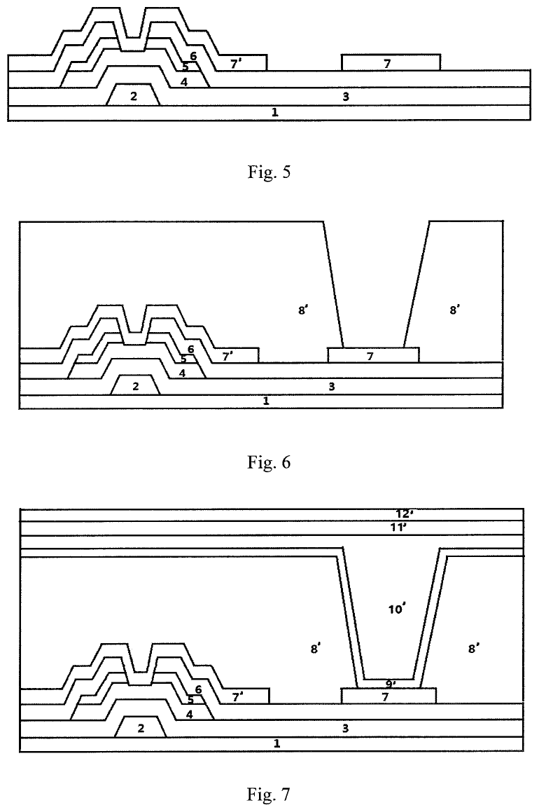

FIG. 3 is a schematic diagram illustrating a detecting substrate of another embodiment of the present disclosure.

As shown in FIG. 3, based on the detecting substrate of the embodiment of the present disclosure shown in FIG. 2, in addition to the part formed between the intrinsic semiconductor layer 10 and the etching protective layer 8, the etching repair layer 9 also includes a part formed between the intrinsic semiconductor layer 10 and the first doped semiconductor layer 7.

In the embodiment of the present disclosure, when the etching repair layer 9 is deposited on an inner wall of the etching protective layer 8, the etching repair layer 9 may also be deposited on the first doped semiconductor layer 7. However, due to a tunneling effect, the part of the etching repair layer 9 formed between the intrinsic semiconductor layer 10 and the first doped semiconductor layer 7 may not affect a carrier transmission in the PIN device, the part of the etching repair layer 9 to be retained to simplify a manufacturing process.

In the embodiment of the present disclosure, since the first doped semiconductor layer 7 is usually made of transparent material, the incident light that does not enter the intrinsic semiconductor layer 10 directly after entering the etching protective layer 8 may irradiate into the intrinsic semiconductor layer 10 through a transmission of the first doped semiconductor layer 7 and a reflection of the lower electrode 6, as shown in FIG. 3. According to the embodiment of the present disclosure, an amount of the incident light absorbed by the intrinsic semiconductor layer 10 may be further increased, and a signal-to-noise ratio of the detecting substrate may be improved.

In one embodiment of the present disclosure, a refractive index of the intrinsic semiconductor layer 10 is larger than that of the etching protective layer 8, so that the incident light entering the intrinsic semiconductor layer 10 from the etching protective layer 8 may be refracted at a required angle and absorbed as much as possible by the intrinsic semiconductor layer 10.

In one embodiment of the present disclosure, the detecting substrate also includes a first encapsulation layer 14 covering the PIN device (see FIG. 9), and the refractive index of the etching protective layer 8 is larger than that of the first encapsulation layer 14, so that the incident light entering the etching protective layer 8 from the first encapsulation layer 14 may refract at a required angle and irradiate as much as possible into the intrinsic semiconductor layer 10.

The embodiments of the present disclosure also provide a photoelectric detection device including the detecting substrate according to any one of the embodiments. The photoelectric detection device may be used as an X-ray detector, but is not limited to this. The photoelectric detection device of the embodiments of the present disclosure has a higher signal-to-noise ratio and a superior detecting performance.

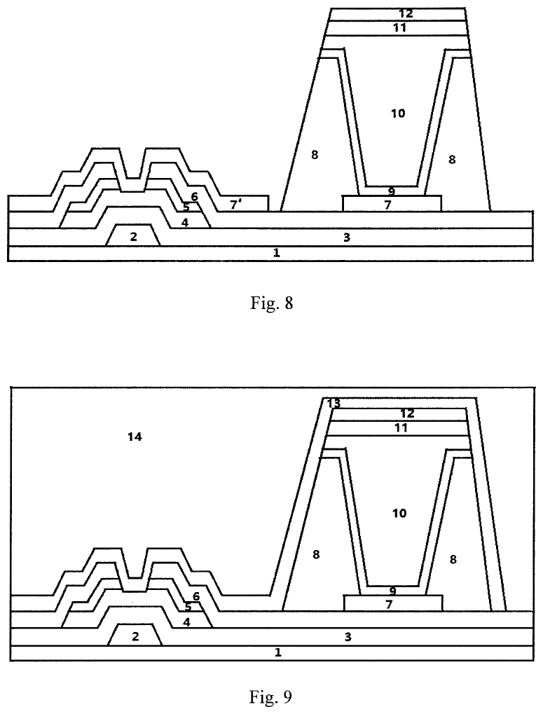

FIG. 4 is a flowchart illustrating a method for manufacturing a detecting substrate of one embodiment of the present disclosure.

As shown in FIG. 4, a method for manufacturing a detecting substrate of the embodiments of the present disclosure, including:

S101, forming a first doped semiconductor thin film on a substrate;

S102, forming an etching protective thin film on the substrate, etching and removing a part of the etching protective thin film at a region where a PIN device is to be formed with an intrinsic semiconductor layer;

S103, forming an intrinsic semiconductor thin film on the etching protective thin film after etching at the region where a PIN device is to be formed;

S104, forming a second doped semiconductor thin film on the intrinsic semiconductor thin film;

S105, etching the etching protective thin film, the intrinsic semiconductor thin film and the second doped semiconductor thin film, and forming a PIN device including a first doped semiconductor layer, the intrinsic semiconductor layer and a second doped semiconductor layer, wherein an etching protective layer is formed by the remaining etching protective thin film covering a side wall of the intrinsic semiconductor layer.

In the manufacturing method of the embodiment of the present disclosure, when the PIN device is manufactured on the substrate, after forming the first doped semiconductor film in S101, an etching protective thin film layer 8′ is formed on the substrate in S102 before forming the intrinsic semiconductor thin film. And a thickness of thus formed etching protective thin film 8′ is equivalent to that of the intrinsic semiconductor thin film to be formed. A part of the etching protective thin film layer 8′ corresponding to a region where a PIN device is to be formed with an intrinsic semiconductor layer is etched and removed, as shown in FIG. 6. Thereafter, an intrinsic semiconductor thin film is formed on the etched region and the etching protective thin film 8′ etched in S103, a second doped semiconductor film is formed on the intrinsic semiconductor thin film in S104, and a single PIN device including the first doped semiconductor layer, the intrinsic semiconductor layer and the second doped semiconductor layer is formed by etching, wherein the remaining etching protective thin film covering a side wall of the intrinsic semiconductor layer is formed to be an etching protective layer. One of the first doped semiconductor thin film and the second doped semiconductor thin film is a P-type semiconductor thin film and the other is an N-type semiconductor thin film, accordingly, in the formed PIN device, One of the first doped semiconductor layer and the second doped semiconductor layer is a P-type semiconductor layer and the other is an N-type semiconductor layer. When the PIN device is etched in S105, most of the etching protective thin film 8′ is etched, and a part of the etching protective thin film 8′ covering the side wall of the intrinsic semiconductor layer is retained as the etching protective layer 8, thus ensuring that the side wall of the intrinsic semiconductor layer of the PIN device is covered by the etching protective layer 8 during the etching process of the PIN device, and etching the side wall of the intrinsic semiconductor layer is avoided, or an etching area of the side wall of the intrinsic semiconductor layer is reduced.

In the embodiment of the present disclosure, when manufacturing the detecting substrate, the etching protective thin film is arranged on the periphery of the intrinsic semiconductor layer for forming the PIN device, and when the PIN device is etched and formed, a part of the etching protective thin film covering the side wall of the intrinsic semiconductor layer is retained as the etching protective layer, such that the side wall of the intrinsic semiconductor layer of the PIN device can be protected from being etched, or an etching area of the side wall of the intrinsic semiconductor layer of the PIN device is reduced, a leakage current caused by the surface defects of crystal materials due to etching at the side wall of intrinsic semiconductor layer is reduced, the incident light absorbed by the intrinsic semiconductor layer may be increased, therefore a signal-to-noise ratio of the detecting substrate is improved.

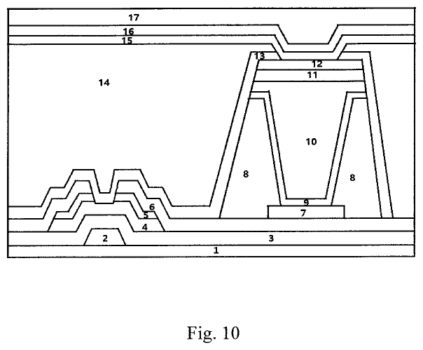

FIG. 5-FIG. 10 are schematic diagrams illustrating processes of a method for manufacturing a detecting substrate of another embodiment of the present disclosure.

In the embodiment of the present disclosure, after manufacturing a substrate 1, firstly a TFT device is manufactured on the substrate 1, including manufacturing a gate metal layer 2 on the substrate 1, depositing a gate insulating layer 3 and an active layer including an amorphous silicon layer 4 and a doped amorphous silicon layer 5 on the gate metal layer 2 and the substrate 1. And then a metal electrode layer 6 is manufactured on the active layer and the gate insulating layer 3. Then a first doped semiconductor thin film is deposited and formed, and patterning the first doped semiconductor thin film is performed to form a channel protective layer 7′ in the TFT device region and the first doped semiconductor layer 7 in the PIN device region, as shown in FIG. 5. It should be noted that the method for manufacturing the TFT device is only illustrative, and the method for manufacturing the TFT device on the substrate in the method for manufacturing the detecting substrate of the present disclosure is not limited to this.

In the embodiment of the present disclosure, by taking that the PIN device to be formed is an N-I-P structure for an example. In the PIN device, the first doped semiconductor layer 7 is an N-type semiconductor layer and the second doped semiconductor layer 11 is a P-type semiconductor layer. When manufacturing, the N-type semiconductor thin film, the intrinsic semiconductor thin film 10′ and the P-type semiconductor thin film are formed successively from the substrate 1. The N-type semiconductor thin film may be made of IGZO, for example. Of course, the present disclosure is not limited to this, and in other embodiments of the present disclosure, the PIN device to be formed may be a P-I-N structure where the first doped semiconductor layer 7 is a P-type semiconductor layer and the second doped semiconductor layer 11 is an N-type semiconductor layer. When manufacturing, the P-type semiconductor thin film, the intrinsic semiconductor thin film 10′ and the N-type semiconductor thin film are formed successively from the substrate 1.

As shown in FIG. 6, the etching protective thin film 8′ is formed on the substrate, and a part of the etching protective thin film 8′ corresponding to a region of the intrinsic semiconductor layer 10 to be formed is etched. A concave part having an etched surface is formed at the region where the PIN device is to be formed.

As shown in FIG. 7, an etching repair thin film 9′ and an intrinsic semiconductor thin film 10′, a second doped semiconductor thin film 11′, and an upper electrode material thin film 12′, are formed respectively at the region where the intrinsic semiconductor 10 is to be formed and on the etching protective thin film 8′ after etching. As shown in FIG. 8, the PIN device including the first doped semiconductor layer 7, the intrinsic semiconductor layer 10, the second doped semiconductor layer 11 and the upper electrode 12 is formed by etching the etching protective thin film 8′, the etching repair thin film 9′, the intrinsic semiconductor thin film 10′, the second doped semiconductor thin layer 11′ and the upper electrode material thin film 12′. At the same time, an etching protective layer 8 covering a side wall of the intrinsic semiconductor layer 10 is formed, and an etching repair layer 9 between the etching protective layer 8 and the intrinsic semiconductor layer 10 is formed. FIG. 8 shows that most of the etching protective thin film 8′ has been etched and removed during the etching process, leaving only a part of the side wall covering the intrinsic semiconductor layer 10 as the etching protective layer 8. As shown in FIG. 9, after forming the PIN device and the etching protective layer 8, the channel protective layer 7′ in the TFT device region is removed, and a passivation layer 13 and a first encapsulation layer 14 are formed on the PIN device and a TFT device successively. As shown in FIG. 10, openings are starts on the passivation layer 13 at the upper electrode 12 of the PIN device to expose at least a part of the upper electrode 12. A transparent electrode layer 15 and a conductive metal layer 16 are manufactured successively at the opening and on the first packaging layer 14, and then a second packaging layer 17 is formed on the conductive metal layer 16 to complete manufacturing the detecting substrate. The first packaging layer 14 and the second packaging layer 17 may be made of resin, for example.

In the embodiment of the present disclosure, the etching protective layer 8 is arranged at the side wall of the intrinsic semiconductor layer 10 of the PIN device in the detecting substrate and the etching repair layer 9 is arranged between the etching protective layer 8 and the side wall of the intrinsic semiconductor layer 10, so that a smoothness of the side wall surface of the intrinsic semiconductor layer 10 may be improved, and a leakage current at the side wall of the intrinsic semiconductor layer 10 may be reduced effectively, a dark current in the PIN device may be reduced, and a signal-to-noise ratio of the detecting substrate may be improved effectively.

In the embodiment of the present disclosure, an inclination angle of an external sidewall and an etching surface of an inner side wall of the etching protective layer 8 may be determined according to refractive indexes of the first packaging layer 14, the etching protective thin film 8′ and the intrinsic semiconductor layer 10, so as to realize a required refractive light path and achieve an effect of focusing light. For example, for the external sidewall of the etching protective layer 8 to be formed, an refractive angle of incident light when entering the etching protective layer 8 to be formed from the encapsulation layer 14 may be determined according to a ratio of a refractive index of the encapsulation layer 14 and a refractive index of the etching protective thin film 8′, and then the inclination angle of an external sidewall of the etching protective layer 8 may be formed according to the refractive angle in the etching process. Then refracted light entering the formed etching protective layer 8 is within a certain angle range relative to the substrate, so as to increase the amount of light irradiating into the intrinsic semiconductor layer 10. For the inner side wall of the etching protective layer 8 to be formed, an refractive angle of incident light when entering the intrinsic semiconductor layer 10 from the etching protective layer 8 to be formed may be determined according to a refractive index of the intrinsic semiconductor layer 10 and a refractive index of the etching protective thin film 8′, and then the inclination angle of an inner etching surface of the etching protective thin film 8′ may be formed according to the refractive angle, so that refracted light entering the intrinsic semiconductor layer 10 from the etching protective layer 8 is within a certain angle range relative to the substrate. The embodiment of the present disclosure, by optimizing device structures, may realize an effect of focusing light, increase the amount of light absorbed by the intrinsic semiconductor layer 10, and improve a signal-to-noise ratio of the detecting substrate.

The above-mentioned embodiments are only optional embodiments of the present disclosure, and do not limit the protection scope required by the present disclosure. Therefore, any equivalent structural changes made by using the description and illustrations of the present disclosure should be included in the protection scope of the present disclosure.

1. A detecting substrate, comprising:
a substrate; and
a photoelectric conversion element formed on the substrate, the photoelectric conversion element is a PIN device comprising a first doped semiconductor layer, an intrinsic semiconductor layer and a second doped semiconductor layer, wherein a side wall of the intrinsic semiconductor layer is covered by an etching protective layer.

2. The detecting substrate according to claim 1, wherein the etching protective layer is made of transparent insulating material.

3. The detecting substrate according to claim 2, further comprising:
an etching repair layer formed between the intrinsic semiconductor layer and the etching protective layer.

4. The detecting substrate according to claim 3, wherein the etching repair layer is also formed between the intrinsic semiconductor layer and the first doped semiconductor layer.

5. The detecting substrate according to claim 3, wherein the etching repair layer is made of transparent insulating material.

6. The detecting substrate according to claim 2, wherein a refractive index of the intrinsic semiconductor layer is larger than that of the etching protective layer.

7. The detecting substrate according to claim 2, wherein the photoelectric conversion element further comprises:
a packaging layer covering the etching protective layer, a refractive index of the etching protective layer being larger than that of the packaging layer.

8. The detecting substrate according to claim 2, wherein the first doped semiconductor layer is made of transparent material.

9. The detecting substrate according to claim 1, wherein the first doped semiconductor layer is a P-type semiconductor layer and the second doped semiconductor layer is an N-type semiconductor layer, or, the first doped semiconductor layer is an N-type semiconductor layer and the second doped semiconductor layer is a P-type semiconductor layer.

10. A photoelectric detection device, comprising the detecting substrate according to claim 1.

11. A method for manufacturing a detecting substrate, comprising:
forming a first doped semiconductor thin film on a substrate;
forming an etching protective thin film on the substrate, etching and removing a part of the etching protective thin film at a region where a PIN device is to be formed with an intrinsic semiconductor layer;
forming an intrinsic semiconductor thin film on the etching protective thin film after etching at the region where a PIN device is to be formed;
forming a second doped semiconductor thin film on the intrinsic semiconductor thin film, wherein one of the first doped semiconductor thin film and the second doped semiconductor thin film is a P-type semiconductor thin film and the other is an N-type semiconductor thin film;
etching the etching protective thin film, the intrinsic semiconductor thin film and the second doped semiconductor thin film, and forming a PIN device comprising a first doped semiconductor layer, the intrinsic semiconductor layer and a second doped semiconductor layer, wherein an etching protective layer is formed by the remaining etching protective thin film covering a side wall of the intrinsic semiconductor layer.

12. The method according to claim 11, wherein subsequent to etching and removing the part of the etching protective thin film at a region where a PIN device is to be formed, the method further comprises:
forming an etching repair layer on an etched surface of the etching protective thin film.

13. The method according to claim 11, wherein:
when etching and removing the part of the etching protective thin film at the region where a PIN device is to be formed, an inclination angle of an etching surface of the etching protective thin film at the region where a PIN device is to be formed is determined based on a refractive index of the intrinsic semiconductor layer and a refractive index of the etching protective thin film.

14. The method according to claim 11, wherein:
when the PIN device is formed by etching, an inclination angle of an external sidewall of the etching protective layer is determined based on a refractive index of an encapsulation layer to be formed on the PIN device and a refractive index of the etching protective thin film.

15. The method according to claim 11, wherein the etching protective thin film is made of transparent insulating material.

16. The method according to claim 12, wherein the etching repair layer is made of transparent insulating material.

17. The detecting substrate according to claim 4, wherein the etching repair layer is made of transparent insulating material.
